(19) United States
(12) Patent Application Publication
(10) Pub. No.: US 2010/0025760 A1
(43) Pub. Date: Feb. 4, 2010

(54) SEMICONDUCTOR DEVICE

(75) Inventor: Yoshiya KAWASHIMA, Kanagawa (JP)

Correspondence Address: YOUNG & THOMPSON, 209 Madison Street, Suite 500, Alexandria, VA, 22314, US

(73) Assignee: NEC Electronics Corporation, Kanagawa (JP)

(21) Appl. No.: 12/499,813

(22) Filed: Jul. 9, 2009

(30) Foreign Application Priority Data
Jul. 31, 2008 (JP) 2008-197831
Nov. 27, 2008 (JP) 2008-302477

(51) Int. Cl. H01L 27/06

(52) U.S. Cl. 257/334; 257/339; 257/288; 257/E27.016; 257/E29.262

(57) ABSTRACT

A semiconductor device includes a MOSFET cell having a super junction structure and a diode cell connected in parallel with the MOSFET cell and having the same plan shape as the MOSFET cell. The MOSFET cell includes an epitaxial layer of a first conductivity type formed on a semiconductor substrate, a gate electrode and a first column region of a second conductivity type formed in the epitaxial layer, a first base region of the second conductivity type formed on a surface of the epitaxial layer, and a source region of the first conductivity type formed on a surface of the first base region. The diode cell includes a second column region of the second conductivity type formed in the epitaxial layer and having a larger width than the first column region, and a second base region of the second conductivity type formed on the surface of the epitaxial layer.

### BACKGROUND

1. Field of the Invention

The present invention relates to a semiconductor device and, particularly, to a high breakdown voltage semiconductor device having a super junction structure.

2. Description of Related Art

A MOS field-effect transistor (MOSFET), an insulated gate bipolar transistor (IGBT) or the like is used as a high breakdown voltage semiconductor device. Important properties of the high breakdown voltage MOSFET are on-resistance and breakdown voltage. The on-resistance and the breakdown voltage depend on the resistivity of an epitaxial layer that is used as an electric-field relaxation layer, and they have a trade-off relationship in which reduction of the resistivity (epitaxial resistance) by increasing the impurity concentration in the epitaxial layer allows a decrease in the on-resistance but causes a decrease in the breakdown voltage at the same time.

The on-resistance of a MOSFET can be represented by the following expression.

Rₒₙ=R_{ct}+R_{ch}+Rₑₚᵢ+R_{sub} Expression 1:

where Rₒₙ: on-resistance
R_{ct}: contact resistance
Rₒₙ: channel resistance
Rₑₚᵢ: epitaxial resistance
R_{sub}: substrate resistance

Expression 1 shows that the on-resistance mainly includes components such as the contact resistance, the channel resistance and the substrate resistance in addition to the epitaxial resistance.

A vertical power MOSFET has a structure that reduces the on-resistance by reducing the channel resistance R_{ch} component. The vertical power MOSFET has a larger total channel width in an element than a horizontal power MOSFET used heretofore, thereby reducing the channel resistance R_{ch} component in the above Expression 1 while maintaining the breakdown voltage. Therefore, the vertical power MOSFET is known as a low on-resistance, high breakdown voltage MOSFET with a higher degree of integration compared to the horizontal power MOSFET.

As a technique of significantly reducing the on-resistance while maintaining the breakdown voltage characteristics in the vertical power MOSFET, a super junction structure has been proposed recently (e.g. Japanese Unexamined Patent Publications Nos. 2006-196518, 2001-313393 and 2006-313892 etc.) FIG. 20 is a plan layout view of a vertical MOSFET semiconductor device 200 having the super junction structure according to prior art. FIG. 21 is a cross-sectional view along line XXI-XXI of FIG. 20. The semiconductor device 200 according to prior art has a plan layout in which unit cells are periodically arranged as shown in the dotted line in FIG. 20. FIG. 20 shows the case where square unit cells are arranged alternately (square staggered arrangement).

Further, in the semiconductor device 200, an epitaxial layer 8 of a first conductivity type (e.g. n-type), which functions as a electric-field relaxation layer, is formed on the principal surface (the upper surface in FIG. 21) of a semiconductor substrate 9 of the first conductivity type. On the surface layer of the epitaxial layer 8, a base region 5 of a second conductivity type (e.g. p-type) is formed. Further, trenches (grooves) that reach a deeper level than the base region 5 are made at given intervals in the epitaxial layer 8, and a gate electrode 4 is formed in each trench with a gate insulating layer, which is not shown, interposed therebetween (a trench gate structure) The gate electrode 4 is placed across the adjacent unit cells.

In the epitaxial layer 8 between the adjacent gate electrodes 4, a column region 1 of the second conductivity type is formed in an island shape. In the epitaxial layer 8, the column region 1 of the second conductivity type is formed in an island shape in each unit cell. Thus, in each unit cell, the super junction structure is formed by the epitaxial layer 8 and the column region 1 that is formed in the epitaxial layer 8. On the surface layer of the base region 5, a source region 3 is formed in contact with each trench. In the center part of each unit cell, a base contact portion 2 in which the source region 3 Is not formed is placed.

On the epitaxial layer 8, an interlayer insulating film 6 is formed to cover the gate electrode 4. Further, a source electrode 7 that is connected to the base region 5 through the base contact portion 2 is formed thereon. Furthermore, a drain electrode 10 is formed on the rear surface (the lower surface in FIG. 21) of the semiconductor substrate 9. The semiconductor device 200 includes three terminals of the drain electrode 10, the source electrode 7 and the gate electrode 4.

As described above, the semiconductor device 200 according to prior art has a structure in which a super junction MOSFET (which is referred to hereinafter simply as an SJ-MOSFET) is placed in each of unit cells arranged regularly. Thus, a plurality of SJ-MOSFET cells are arranged in a regular manner in the semiconductor device 200.

In the semiconductor device 200 having such a structure, if a reverse bias voltage is applied between the drain and the source in the static state where a bias voltage is not applied between the gate and the source (the off-state of the SJ-MOSFET), a depletion layer extends from two p-n junction planes, which are a p-n junction plane between the base region 5 and the epitaxial layer 8 and a pin junction plane between the column region 1 and the epitaxial layer 8. Due to the depletion layer, leakage current between the drain and the source is suppressed, so that the breakdown voltage is maintained. Because the column region 1 extends in the vertical direction of the SJ-MOSFET cell, the depletion layer by the p-n junction plane between the column region 1 and the epitaxial layer 8 also extends in the horizontal direction of the SJ-MOSFET cell. Then, the entire part of the column region 1 and the epitaxial layer 8 becomes depleted. Consequently, the breakdown voltage of the semiconductor device 200 ceases to depend on the impurity concentration of the epitaxial layer 8, so that it is determined based only on the thickness of the epitaxial layer 8.

Therefore, with use of the super junction structure, it is possible to maintain the breakdown voltage while reducing the on-resistance by increasing the impurity concentration of the epitaxial layer 8. Further, it is possible to adjust the breakdown voltage by the thickness of the epitaxial layer 8, which enables an increase in variety of combinations of the on-resistance and the breakdown voltage in the semiconductor device 200.

An example of the vertical SJ-MOSFET having the above structure is disclosed in Japanese Unexamined Patent Publication No. 2006-196518. In Japanese Unexamined Patent Publication No. 2006-196518, the column region 1 is formed continuously in the depth direction of the epitaxial layer 8, with a depth that does not reach the interface with the semiconductor substrate 9. The shape of the column formed in the vertical SJ-MOSFET has several types, and other types are disclosed in Japanese Unexamined Patent Publications Nos. 2001-313393 and 2006-313892, Proceedings of the 19th International Symposium on Power Semiconductor Devices & ICI's, P.37, 2007, and Proceedings of the 18th International Symposium on Power Semiconductor Devices & IC's, P.301, 2006 and so on. For example, the column disclosed in Japanese Unexamined Patent Publication No. 2001-313393 is formed discretely in the depth direction. On the other hand, the column disclosed in Proceedings of the 19th International Symposium on Power Semiconductor Devices & IC's, P.37, 2007 is formed with a depth that reaches the substrate interface.

In the semiconductor device 200 according to prior art, the column region 1 is formed in such a way that the impurity concentration Qₚ of the second conductivity type in the column region 1 is higher than the impurity concentration Qₙ of the first conductivity type in the epitaxial layer 8 and the column diameter is large. This is because of the following reason. In the SJ-MOSFET cell, a breakdown current due to load energy from an external line or the like occurs in addition to a current due to residual minority carrier in close proximity to the p-n junction interface when switching from the on-state to the off-state, and it is necessary to consume those currents within the cell. If the current path is formed in close proximity to the trench gate, dielectric breakdown due to injection of hot carriers into the gate insulating layer or the like, thermal breakdown due to activation of parasitic bipolar formed along the trench side wall and so on occur.

FIG. 22 is a graph showing variation of the breakdown voltage of the SJ-MOSFET with respect to the charge balance state between the epitaxial layer and the column (cf. Japanese Unexamined Patent Publication No. 2006-313892). As shown in FIG. 22, the drain-source breakdown voltage (D-S breakdown voltage) varies with the charge balance between the impurity concentration Qₚ in the column region 1 and the impurity concentration Qₙ in the epitaxial layer 8 and reaches its maximum at Qₚ=Qₙ. Then, if Qₚ becomes larger than the balance state of Qₚ=Qₙ by increasing the column diameter or the impurity concentration, an electric field is maximized at the bottom of the column region 1, and the bottom part can serve as a breakdown voltage determination point. In this manner, in order to enhance the avalanche capability by forming the breakdown current path at the center of the column region 1 that is sufficiently separated from the trench gate, the column diameter is enlarged and the concentration of the impurity of the second conductivity type added to the column region 1 is increased to satisfy Qₚ>Qₙ.

In the semiconductor device 200, during the charge balance state of Qₚ>Qₙ, the depletion layer extends from the p-n junction plane when the SJ-MOSFET is in the off state. At this time, in the part of the epitaxial layer 8 up to the depth at which the column region 1 is formed, a certain amount of depletion occurs in the horizontal direction along the side wall of the column region 1, so that the electric field between the source and the drain is relaxed. On the other hand, the depletion layer extending in the vertical direction along the bottom of the column region 1 is unable to completely relax the electric field because the source-drain electric field is applied, and avalanche breakdown occurs at the bottom of the column region 1. Thus, the bottom of the column region 1 serves as a breakdown voltage determination point of the semiconductor device 200. The carrier generated by the avalanche breakdown moves to the source electrode 7 through the column region 1 and the base region 5, so that a breakdown current is generated. Because the breakdown current path is formed at the center of the column region 1 that is sufficiently separated from the trench gate as described above, it is possible to prevent dielectric breakdown due to injection of hot carriers into the gale insulating layer or the like, thermal breakdown due to activation of parasitic bipolar formed along the trench side wall and so on.

FIG. 23 is a graph showing variation of the avalanche capability and the on-resistance with respect to the charge balance state between the epitaxial layer and the column in the semiconductor device 200 according to prior art In FIG. 23, a limiting current Iₘₐₓ in the unclamped inductive switching (UIS) test where a certain line load is added to an external circuit is used as a parameter indicating the avalanche capability (cf. Proceedings of the 18th International Symposium on Power Semiconductor Devices & IC's, P.301, 2006). It is obvious from FIG. 23 that, under the condition to satisfy Qₚ>Qₙ by increasing the column diameter or the impurity concentration of the column region 1, Iₘₐₓ becomes larger and the avalanche capability is sufficiently enhanced. However, due to an increase in the column diameter, the epitaxial layer 8 to serve as the on-current path is reduced, and the current path is limited. As a result, the on-resistance Rₒₙ increases, and the on-resistance characteristics are degraded. The increase in the on-resistance Rₒₙ is caused by an increase in the epitaxial resistance Rₑₚᵢ component in the above Expression 1.

The epitaxial resistance Rₑₚᵢ is a dominant component of the on-resistance Rₒₙ and represented by the following expression:

Rₑₚᵢ∝(1−(N/1100))−1 Expression 2:

where N is occupancy (%) of the column region of the second conductivity type per unit area Expression 2 shows that, if the value of Qₚ is increased only by enlarging the column diameter while maintaining a constant amount of impurity added to the column region 1 per unit area in the semiconductor device 200, Rₑₚᵢ increases in quadratic function manner. Accordingly, the on-resistance Rₒₙ increases in quadratic function manner with an increase in Qₚ as shown in FIG. 23. In the manufacturing process of the semiconductor device 200, even if trying to increase the concentration of impurity added to the column region 1 per unit area while maintaining a constant column diameter, the impurity is diffused by heat treatment or the like, and the column diameter is substantially enlarged. It is thereby difficult to suppress an increase in the on-resistance under the condition of Qₚ>Qₙ.

To address the above concern, a technique of increasing the breakdown voltage while maintaining the on-resistance by using a diode is disclosed in Japanese Unexamined Patent Publication No. 9-102607, United States Patent Publication No. 5,998,836, United States Patent Publication No. 5,998,837, United States Patent Publication No. 6,140,678, Japanese Unexamined Patent Publication No. 2003-298053, and Japanese Unexamined Patent Publication No 2006-24690. In the technique of Japanese Unexamined Patent Publication No. 9-102607, United States Patent Publication No. 5,998,836, United States Patent Publication No. 5,998,837 and United States Patent Publication No. 6,140,678, a part of the MOSFET cells arranged regularly in the semiconductor device is substituted with a diode cell, and the depth of P⁺ base of the diode cell is set larger or smaller than other MOSFET cells. The diode cell is thereby set as a breakdown voltage determination point, thereby enhancing the avalanche capability. However, because the column is not formed in the MOSFET described in Japanese Unexamined Patent Publication No. 9-102607, United States Patent Publication No. 5,998,836, United States Patent Publication No. 5,998,837 and United States Patent Publication No. 6,140,678, the MOSFET has a different structure from the super junction structure. Further, in the technique of Japanese Unexamined Patent Publication No. 2003-298053, an n-type drift layer and a p-type drift layer are formed in an n-type drain layer, and a barrier insulating layer is formed between the n-type drift layer and the p-type drift layer, in contact therewith. However, the MOSFET described in Japanese Unexamined Patent Publication No. 2003-298053 has a particular structure that the super junction structure is formed by the barrier insulating layer. On the other hand, the technique of Japanese Unexamined Patent Publication No. 2006-24690 provides the structure having the super junction structure made up of an n⁻ drift layer and a p⁻ pillar layer formed in the n⁻ drift layer.

FIG. 24 is a cross-sectional view showing the structure of an SJ-MOSFET semiconductor device 300 that includes a diode according to prior art, which is disclosed in Japanese Unexamined Patent Publication No. 2006-24690. As shown in FIG. 24, the semiconductor device 300 includes a power MOSFET 310 and a Schottky barrier diode (SBD) 320.

The power MOSFET 310 has the super junction structure that is formed by an n⁻ drift layer 311 and a plurality of p⁻ pillar layers 312 formed in the n⁻ drift layer 311. On the upper surface region of the n⁻ drift layer 311, p-type base layers 315 that are placed for the respective p⁻ pillar layers 312 and connected to the corresponding p⁻ pillar layers 312 are formed in a stripe pattern in the vertical direction of FIG. 24. The n⁻ drift layer 311 between the p-type base layers 315, the two adjacent p-type base layers 315 and a gate insulating layer 318 in contact with an n-type source layer 316 placed on those p-type base layers 315 are formed to extend in the vertical direction. Further, gate electrodes 319 are formed on the gate insulating layer 318 in a stripe pattern extending in the vertical direction. Furthermore, in the region between the adjacent gate electrodes 319, source electrodes 317 in contact with the n-type source layer 316 and the p-type base layer 315 are formed in a stripe pattern in the vertical direction.

On the other hand, the SBD 320 is connected in parallel between the source and drain electrodes of the power MOSFET 310. In the SBD 320, the super junction structure is formed by an n⁻ drift layer 322 and a plurality of p⁻ pillar layers 323 formed in the n⁻ drift layer 322. On the upper surface region of the n⁻ drift layer 322, guard ring layers 324 that are placed for the respective p⁻ pillar layers 323 and connected to the corresponding p⁻ pillar layers 323 are formed in a stripe pattern in the vertical direction of FIG. 24. Further, an anode electrode 325 is placed in contact with the adjacent guard ring layers 324 and the n⁻ drift layer 322 between those guard ring layers 324. The anode electrode 325 is connected to a source terminal 333 of the power MOSFET 310. By placing the SBD 320, it is possible to increase the breakdown voltage while maintaining the on-resistance of the semiconductor device 300.

However, in the semiconductor device 300 disclosed in Japanese Unexamined Patent Publication No. 2006-24690, the layout of the SBD 320 is different from that of the power MOSFET 310. Specifically, the power MOSFET 310 and the SBD 320 are different not only in the presence or absence of the n-type source layer 316 but also in the structure of the gate electrodes 319. Further, the area of the SBD 320 is larger than that of the power MOSFET 310 so as to ensure an increase in the breakdown voltage. Therefore, the semiconductor device 300 has a complicated structure, and it thus takes a lot of trouble to change the area and layout when placing the SBD 320 in substitution for the power MOSFET 310 It is thereby unable to freely change the installation location and the number of the SBD 320.

### SUMMARY

An exemplary aspect of an embodiment of the present invention is a semiconductor device that includes a metal-oxide semiconductor field-effect transistor (MOSFET) cell having a super junction structure, and a diode cell connected in parallel with the MOSFET cell and having the same plan shape as the MOSFET cell. The MOSFET cell includes an epitaxial layer of a first conductivity type formed on a semiconductor substrate, a gate electrode formed in a trench of the epitaxial layer with an insulating layer interposed therebetween, a first column region of a second conductivity type formed in the epitaxial layer, a first base region of the second conductivity type formed on a surface of the epitaxial layer, and a source region of the first conductivity type formed on a surface of the first base region. The diode cell includes a second column region of the second conductivity type formed in the epitaxial layer, the second column region having a larger width than the first column region, and a second base region of the second conductivity type formed on the surface of the epitaxial layer.

In this structure the diode cell that is different from the MOSFET cell only in the presence or absence of the source region and the width of the column region is placed. It is thereby possible to freely change the installation location and the number of the diode cell in the semiconductor device including the MOSFET cell having the super junction structure.

According to the exemplary aspect of an embodiment of the present invention described above, it is possible to provide a semiconductor device having a high breakdown voltage and low on-resistance with a simple structure.

### BRIEF DESCRIPTION OF THE DRAWINGS

The above and other objects, advantages and features of the present invention will be more apparent from the following description of certain exemplary embodiments taken in conjunction with the accompanying drawings, in which:

FIG. 1 is a plan layout view of a semiconductor device according to a first exemplary embodiment;

FIG. 2 is a cross-sectional view along Line II-II in FIG. 1;

FIG. 3 is a graph showing relationship between a column diameter and a drain-source breakdown voltage of an SJ-MOSFET cell and a diode cell of the semiconductor device according to the first exemplary embodiment;

FIG. 4 is a plan layout view of a semiconductor device according to a second exemplary embodiment;

FIG. 5 is a cross-sectional view along line V-V in FIG. 4;

FIG. 6 is a cross-sectional view of a semiconductor device according to a third exemplary embodiment;

FIG. 7 is a cross-sectional view of a semiconductor device according to a fourth exemplary embodiment;

FIG. 8 is a plan layout view of a semiconductor device according to a fifth exemplary embodiment;

FIG. 9 is a cross-sectional view along line IX-IX in FIG. 8;

FIG. 10 is a cross-sectional view of a semiconductor device according to another example of the fifth exemplary embodiment;

FIG. 11 is a cross-sectional view of a semiconductor device according to yet another example of the fifth exemplary embodiment; and

FIG. 12 is a plan layout view of a semiconductor device according to still another example of the fifth exemplary embodiment;

FIG. 13 is a cross-sectional view along line XIII-XIII in FIG. 12;

FIG. 14 is a plan layout view of a semiconductor device according to a sixth exemplary embodiment;

FIG. 15 is a cross-sectional view along line XV-XV in FIG. 14;

FIG. 16 is a plan layout view of a semiconductor device according to a seventh exemplary embodiment;

FIG. 17 is a cross-sectional view along line XVII-XVII in FIG. 16;

FIG. 18 is a plan layout view of a semiconductor device according to an eighth exemplary embodiment;

FIG. 19 is a cross-sectional view along line XIX-XIX in FIG. 18;

FIG. 20 is a plan layout view of a vertical MOSFET semiconductor device having a super junction structure according to prior art;

FIG. 21 is a cross-sectional view along line XXI-XXI in FIG. 20;

FIG. 22 is a graph showing variation of a breakdown voltage of an SJ-MOSFET with respect to a charge balance state between an epitaxial layer and a column;

FIG. 23 is a graph showing variation of avalanche capability and on-resistance with respect to a charge balance state between an epitaxial layer and a column in a semiconductor device according to prior art; and

FIG. 24 is a cross-sectional view showing the structure of an SJ-MOSFET semiconductor device including a diode according to prior art.

### DETAILED DESCRIPTION OF THE EXEMPLARY EMBODIMENTS

Preferred embodiments of the present invention will be described hereinbelow. The explanation provided hereinbelow merely illustrates exemplary embodiments of the present invention, and the present invention is not limited to the below-described embodiments. The following description and the accompanying drawings are appropriately shortened and simplified to clarify the explanation. Further, redundant explanation is omitted as appropriate to clarify the explanation. In the figures, the identical reference symbols denote identical elements and the explanation thereof is omitted as appropriate.

### First Exemplary Embodiment

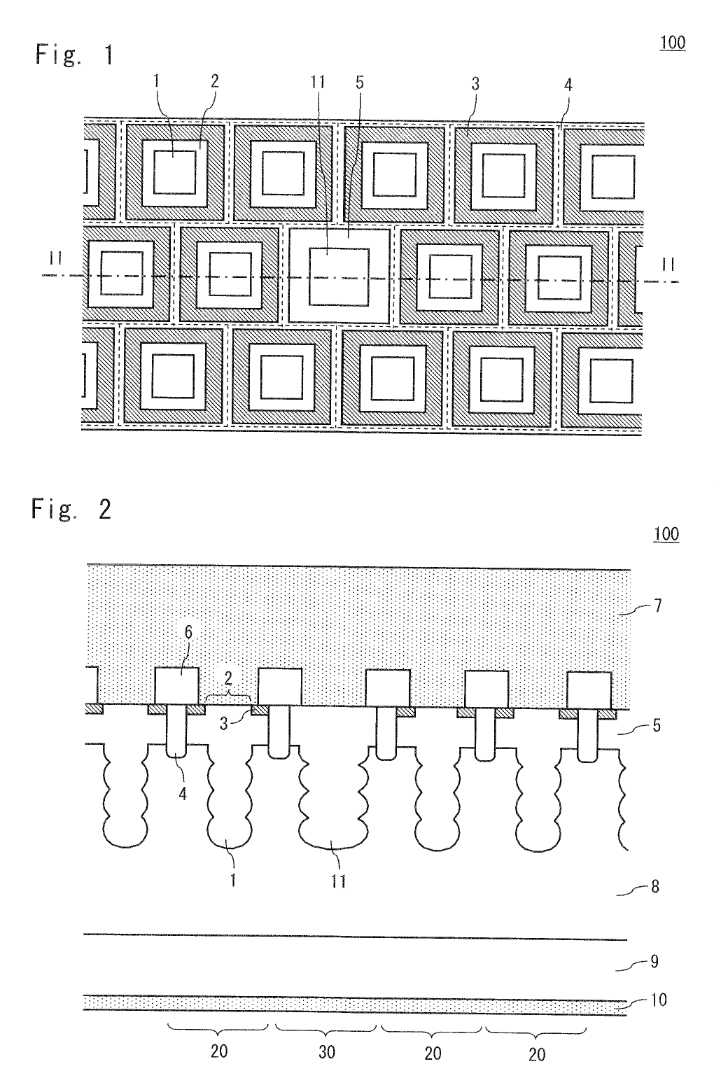

The structure of a semiconductor device according to an exemplary embodiment of the present invention is described hereinafter with reference to FIGS. 1 and 2. FIG. 1 is a plan layout view of a semiconductor device 100 according to a first exemplary embodiment. FIG. 2 is a cross-sectional view along line II-Il in FIG. 1. The semiconductor device 100 according to the exemplary embodiment has a plan layout in which unit cells are periodically arranged as shown in the dotted line in FIG. 1. FIG. 1 shows the case where square unit cells are arranged alternately (square staggered arrangement) by way of illustration. The pitch size of the unit cell is 5 μm, for example.

The semiconductor device 100 according to the exemplary embodiment includes an SJ-MOSFET cell in which an SJ-MOSFET 20 is formed and a diode cell in which a diode 30 is formed as shown in FIGS. 1 and 2. The SJ-MOSFET cell or the diode cell is formed in each unit cell shown in FIG. 1. Thus, a part of a plurality of SJ-MOSFET cells that are arranged regularly in the semiconductor device 100 is substituted with a diode cell. Therefore, in FIG. 1, the plan shape of one SJ-MOSFET cell and the plan shape of one diode cell are the same. Accordingly, the diode cell has the same area as the SJ-MOSFET cell. FIG. 1 shows the case where one diode cell is placed by way of illustration.

In the semiconductor device 100, an epitaxial layer 8 of a first conductivity type (e.g. n-type), which functions as a electric-field relaxation layer, is formed on the principal surface (the upper surface in FIG. 2) of a semiconductor substrate 9 of the first conductivity type as shown in FIG. 2. For example, the epitaxial layer 8 with a specific resistance of 0.4 Ω·cm and a thickness of 5.0 μm is formed. On the surface layer of the epitaxial layer 8, a base region 5 of a second conductivity type (e.g. p-type) is formed. In the base region 5, an impurity of the second conductivity type is implanted under the conditions of an energy of 130 keV and a dose amount of 8.0E¹² atms/cm².

Further, trenches (grooves) that reach a deeper level than the base region 5 are made at given intervals in the epitaxial layer 8, and a gate electrode 4 is formed in each trench with a gate insulating layer, which is not shown, interposed therebetween (a trench gate structure). Each gate electrode 4 is formed on the periphery of the unit cell and disposed across the adjacent unit cells. In this example, the gate electrodes 4 are formed to surround each unit cell as shown in FIG. 1. Accordingly, the gate electrodes 4 are formed in a mesh pattern on the principal surface of the semiconductor substrate 9. The base region 5 is surrounded by the gate electrodes 4 and separated from the base region 5 of the adjacent unit cell by the gate electrodes 4. The base region 5 is placed between the adjacent gate electrodes 4. The base region 5 is an area where a channel is formed when a voltage is applied to the gate electrode 4.

In the SJ-MOSFET cell, a column region 1 of the second conductivity type is formed in the epitaxial layer 8 between the adjacent gate electrodes 4, as in the semiconductor device 200 according to prior art shown in FIG. 21. In the epitaxial layer 8, the column region 1 of the second conductivity type is formed in an island shape in each SJ-MOSFET cell. Thus, each SJ-MOSFET cell has a super junction structure that is formed by the epitaxial layer 8 and the column region 1 formed in the epitaxial layer 8. In this example, the column region 1 is formed with a depth that does not reach the interface of the epitaxial layer 8 with the semiconductor substrate 9, which is a depth to be separated from the semiconductor substrate 9. The column region 1 is formed continuously in the depth direction. The gate electrode 4 is placed on the periphery of the column region 1 in the plan view.

On the surface layer of the base region 5, a source region 3 is formed in contact with each trench. In the center part of each SJ-MOSFET cell, a base contact portion 2 in which the source region 3 is not formed is placed. Thus, the source region 3 is placed on the periphery of each SJ-MOSFET cell so as to surround the base contact portion 2.

On the other hand, in the diode cell, a column region 11 of the second conductivity type is formed in the epitaxial layer 8 between the adjacent gate electrodes 4. In the epitaxial layer 8, the column region 11 of the second conductivity type is formed in an island shape in each diode cell. Thus, each diode cell has a super junction structure that is formed by the epitaxial layer 8 and the column region 11 formed in the epitaxial layer 8. In this example, the column region 11 is formed with a depth to be separated from the semiconductor substrate 9. The column region 11 is formed with the same depth as the column region 1 of the SJ-MOSFET cell. In the diode cell, the gate electrodes 4 are arranged in the same layout as in the SJ-MOSFET cell. The gate electrode 4 is placed on the periphery of the column region 11 in the plan view. In the diode cell, the source region 3 is not formed on the surface layer of the base region 5. Thus, the source region 3 is placed only in the SJ-MOSFET cell.

On the epitaxial layer 8, an interlayer insulating film 6 is formed to cover the gate electrode 4. Further, a source electrode 7 is formed thereon. The source electrode 7 is connected to the base region 5 of the SJ-MOSFET cell through the base contact portion 2. The source electrode 7 is also connected to the base region 5 of the diode cell through an opening of the interlayer insulating film 6. Furthermore, a drain electrode 10 is formed on the rear surface (the lower surface in FIG. 2) of the semiconductor substrate 9. The semiconductor device 100 includes three terminals of the drain electrode 10, the source electrode 7 and the gate electrode 4. As described above, the plurality of SJ-MOSFETs 20 and the diode 30 are arranged in parallel with each other.

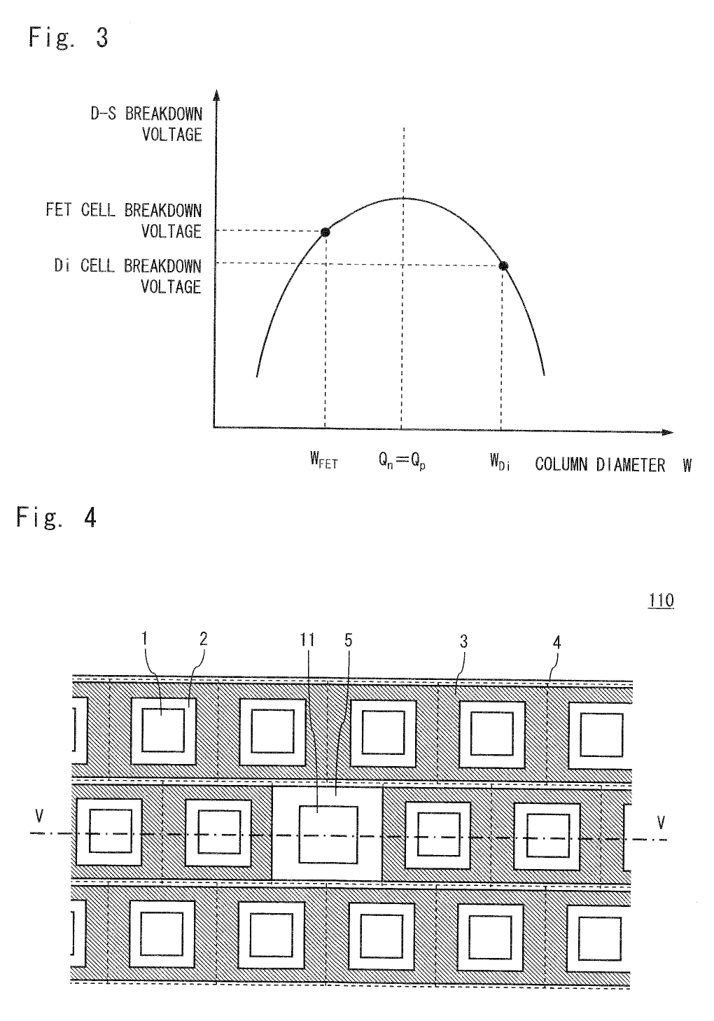

The column region 1 of the SJ-MOSFET 20 and the column region 11 of the diode 30 are described hereinafter in detail with reference to FIG. 3. FIG. 3 is a graph showing relationship between the column diameter and the drain-source breakdown voltage of the SJ-MOSFET cell and the diode cell in the semiconductor device 100 according to the first exemplary embodiment. In this exemplary embodiment, as shown in FIG. 3, the column diameter (column width) W_{Di} of the column region 11 of the diode cell is set to be larger than the balance state of Qₚ=Qₙ, so that the impurity concentration Qₚ of the second conductivity type in the column region 11 is higher than the impurity concentration Qₙ of the first conductivity type in the epitaxial layer 8. On the other hand, the column diameter W_{FET} of the column region 1 of the SJ-MOSFET cell is set in the range where the breakdown voltage of the SJ-MOSFET cell is kept higher than the breakdown voltage of the diode cell.

In other words, the column diameter W_{Di} of the diode cell is set to be larger than the column diameter W_{FET} of the SJ-MOSFET cell with the charge balance state of Qₚ>Qₙ. Because the breakdown voltage of the diode cell is thereby lower than the breakdown voltage of the SJ-MOSFET cell, avalanche breakdown can occur at the bottom of the column region 11 of the diode cell. Because the breakdown current path is formed at the center of the column region 11 that is sufficiently separated from the -trench side wall, it is possible to obtain sufficiently high avalanche capability in the diode cell. Further, because the diode cell does not include the source region 3, thermal breakdown due to activation of parasitic bipolar formed along the trench side wall is suppressed. Furthermore, because the semiconductor device 100 according to the exemplary embodiment enables reduction of the column diameter W_{FET} of the SJ-MOSFET cell compared to the semiconductor device 200 according to prior art that does not include the diode cell, it is possible to reduce the on-resistance while maintaining the avalanche capability.

The column regions 1 and 11 are formed by ion implantation with a dose amount fixed to 6.0E¹² atms/cm² and an energy changing at four levels of 2.0 MeV, 1.5 MeV, 1.0 MeV and 0.5 MeV, from the deeper side, for example. Under such conditions, the balance state of Qₚ=Qₙ is obtained when the column diameter W is half the cell pitch of the unit cell, which is 2.5 μm in this example. Therefore, the column regions 1 and 11 in which the column diameter W_{Di} of the diode cell is 2.9 μm and the column diameter W_{FET} of the SJ-MOSFET cell is 2.3 μm are formed, for example.

In the semiconductor device 100 having the above structure, the normalized on-resistance per unit chip area excluding the substrate resistance R_{sub} component from the parameters forming the on-resistance Rₒₙ of Expression 1 is 20 mΩ·mm², for example. The substantial thickness of the epitaxial layer 8 is about 3.2 μm, taking the dopant diffusion from the semiconductor substrate 9 and the thickness of the base region 5 into account. If the normalized on-resistance is decomposed into the respective components of Expression 1, the Rₑₚᵢ component is 14 mΩ·mm², and the R_{ct} component+R_{ch} component is 6 mΩ·mm². Further, in the semiconductor device 100 according to the exemplary embodiment, the column occupation area ratio N of the SJ-MOSFET cell is 21%.

If it is assumed that the column region 1 with the column diameter W_{FET} of 2.9 μm is formed in the semiconductor device 200 according to prior art that does not include the diode cell, the column occupation area ratio N is 34%. Accordingly, based on Expression 2, the Rₑₚᵢ component is reduced by 17% in the semiconductor device 100 according to the exemplary embodiment compared to the semiconductor device 200 according to prior art. Thus, the normalized on-resistance is reduced by 2.4 mΩ·mm².

On the other hand, because the on-current does not flow through the diode cell in which the source region 3 is not formed, the on-resistance increases in the semiconductor device 100 according to the exemplary embodiment compared to the semiconductor device 200 according to prior art, so that all of the R_{ct} component, the R_{ch} component and the Rₑₚᵢ component excluding the R_{sub} component increase. For example, in the case where one diode cell is placed per twenty-five SJ-MOSFET cells in the semiconductor device 100, the on-resistance Rₒₙ increases by 4% compared to the semiconductor device 200 according to prior art, and the normalized on-resistance increases by 0.8 mΩ·mm². As a result, reduction of the normalized on-resistance by 1.6 mΩ·mm² can be achieved overall.

As described in the foregoing, in this exemplary embodiment, the diode cell is formed in such a way that only the presence or absence of the source region 3 and the width of the column region are different from those of the SJ-MOSFET cell. The semiconductor device 100 thus has a simple structure, and it does not take much trouble to change the plan shape or the layout of the gate electrodes 4 when placing the diode cell in substitution for the SJ-MOSFET cell. It is thereby possible to freely change the installation location and the number of the diode cell in the semiconductor device 100. The change may be made simply by altering the mask of the source region 3. Further, the column diameter W_{FET} of the column region 1 formed in the SJ-MOSFET cell is smaller than the column diameter W_{Di} of the column region 11 formed in the diode cell, so that it is possible to further reduce the on-resistance while maintaining the breakdown voltage. It is thereby possible to provide the semiconductor device having a high breakdown voltage and low on-resistance with a simple structure.

In the semiconductor device 100, the ratio of the number of diode cells with respect to the number of SJ-MOSFET cells may be determined arbitrarily. Further, the diode cells may be arranged periodically or randomly as long as the ratio with respect to the number of SJ-MOSFET cells is kept within a desired range.

Further, although the dependence of the breakdown voltage on the charge balance as shown in the graph of FIG. 3 is used as a method of adjusting the breakdown voltage of the SJ-MOSFET cell to be higher than the breakdown voltage of the diode cell in the above description, the present invention is not limited thereto, and another method may be used. For example, a method may be used that optimizes the column diameter in such a way that the breakdown part is in the diode cell with use of a method of checking the avalanche breakdown capability such as the UIS test described earlier.

### Second Exemplary Embodiment

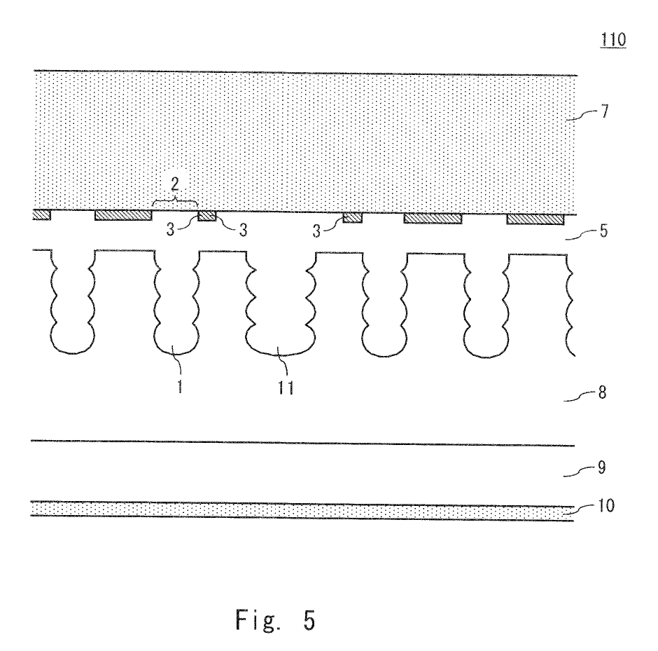

The structure of a semiconductor device according to another exemplary embodiment of the present invention is described hereinafter with reference to FIGS. 4 and 5. FIG. 4 is a plan layout view of a semiconductor device 110 according to a second exemplary embodiment. FIG. 5 is a cross-sectional view along line V-V in FIG. 4. The semiconductor device 110 according to the exemplary embodiment has a plan layout in which unit cells are periodically arranged as shown in the dotted line in FIG. 5. FIG. 5 shows the case where square unit cells are arranged alternately (square staggered arrangement) by way of illustration. In this exemplary embodiment, the layout of the gate electrodes 4 is different from that of the first exemplary embodiment. The other structure is the same as that of the first exemplary embodiment and thus not repeatedly described.

Referring to FIG. 4, in the semiconductor device 110 according to the exemplary embodiment, the gate electrode 4 is formed linearly in one direction on the principal surface of the semiconductor substrate 9. A plurality of linear gate electrodes 4 are formed at given intervals. The plurality of gate electrodes 4 are arranged in parallel with each other. Further, the column regions 1 and 11 are placed discretely between the adjacent gate electrodes 4. Thus, the base region 5 is formed continuously, being connected between the adjacent unit cells in the horizontal direction as shown in FIG. 5. The gate electrode 4 is placed on the periphery of the column regions 1 and 11 in the plan view.

In this structure, the layout of the gate electrodes 4 is simplified. It is thereby possible to facilitate the manufacture when the cell pitch is finer. It is further possible to reduce the gate capacitance because the total length of the gate electrodes 4 is reduced in the semiconductor device 110. Furthermore, the same advantages as the first exemplary embodiment can be obtained.

### Third Exemplary Embodiment

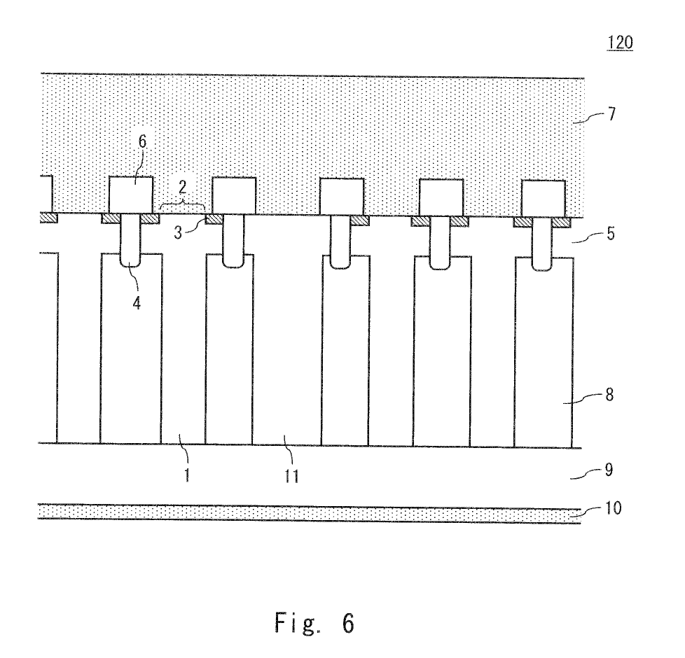

The structure of a semiconductor device according to another exemplary embodiment of the present invention is described hereinafter with reference to FIG. 6. FIG. 6 is a cross-sectional view of a semiconductor device 120 according to a third exemplary embodiment. FIG. 6 is a cross-sectional view along line II-II in FIG. 1, just like FIG. 2. In this exemplary embodiment, the depth of the column regions 1 and 11 is different from that of the first exemplary embodiment. The other structure is the same as that of the first exemplary embodiment and thus not repeatedly described.

Referring to FIG. 6, in the semiconductor device 120 according to the exemplary embodiment, the column region 1 of the SJ-MOSFET cell and the column region 11 of the diode cell are formed with a depth that reaches the interface of the epitaxial layer 8 with the semiconductor substrate 9. Accordingly, the bottom surfaces of the column regions 1 and 11 are in contact with the semiconductor substrate 9. Further, the column regions 1 and 11 are formed continuously in the depth direction (the vertical direction in FIG. 6). The column regions 1 and 11 have columnar shapes in this example.

As described above, in this exemplary embodiment, the column regions 1 and 11 are formed at the maximum depth in the epitaxial layer 8. In this structure, the depletion layer extending in the horizontal direction from the p-n junction plane between the column region 1 and the epitaxial layer 8 is maximized in the off-state of the SJ-MOSFET. It is thereby possible to maximize the breakdown voltage of the semiconductor device 120. Further, the same advantages as the first exemplary embodiment can be obtained.

### Fourth Exemplary Embodiment

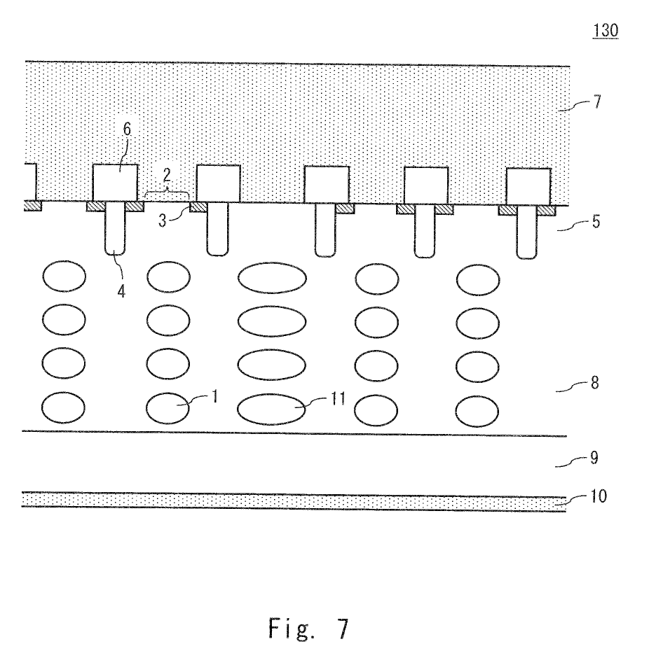

The structure of a semiconductor device according to another exemplary embodiment of the present invention is described hereinafter with reference to FIG. 7. FIG. 7 is a cross-sectional view of a semiconductor device 130 according to a fourth exemplary embodiment. FIG. 7 is a cross-sectional view along line II-II in FIG. 1, just like FIGS. 2 and 6. In this exemplary embodiment, the shape of the column regions 1 and 11 is different from that of the first exemplary embodiment. The other structure is the same as that of the first exemplary embodiment and thus not repeatedly described.

Referring to FIG. 7, in the semiconductor device 130 according to the exemplary embodiment, the column region 1 of the SJ-MOSFET cell and the column region 11 of the diode cell are formed discretely in the thickness direction of the epitaxial layer 8 (the vertical direction in FIG. 7). Thus, in one SJ-MOSFET cell, a plurality of column regions 1 are disposed to be spaced from each other in the thickness direction of the epitaxial layer 8. Further, in one diode cell, a plurality of column regions 11 are disposed to be spaced from each other in the thickness direction of the epitaxial layer 8. In this example, four column regions 1 and 11 are formed in the thickness direction of the epitaxial layer 8.

As described above, in this exemplary embodiment, the column regions 1 and 11 are formed discontinuously in the thickness direction of the epitaxial layer 8. In this structure, the depletion layer from the p-n junction plane between the column region 1 and the epitaxial layer 8 extends in the horizontal direction and the vertical direction in the off-state of the SJ-MOSFET. When the entire epitaxial layer 8 is depleted, a part where the electric field by negatively-charged acceptor ions from the respective p-type column regions 1 and positively-charged donor ions in the n-type epitaxial layer 8 is in the same direction as the bias applied between the source and the drain is created. The part where the directions coincide is created on the interface between the respective column regions 1 and the epitaxial layer 8, and the electric field is enhanced. Consequently, impact ionization occurs in close proximity to the bottom of the respective column regions 1, and it is thereby possible to further suppress the extension of the breakdown current to the trench gate electrode 4 side. Further, the same advantages as the first exemplary embodiment can be obtained.

### Fifth Exemplary Embodiment

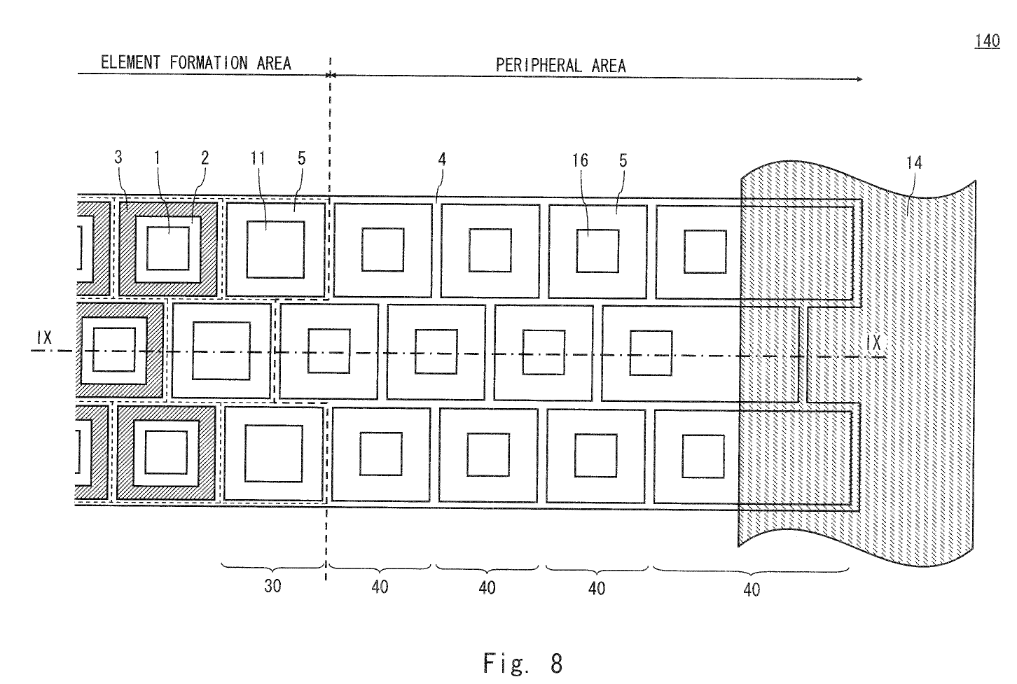

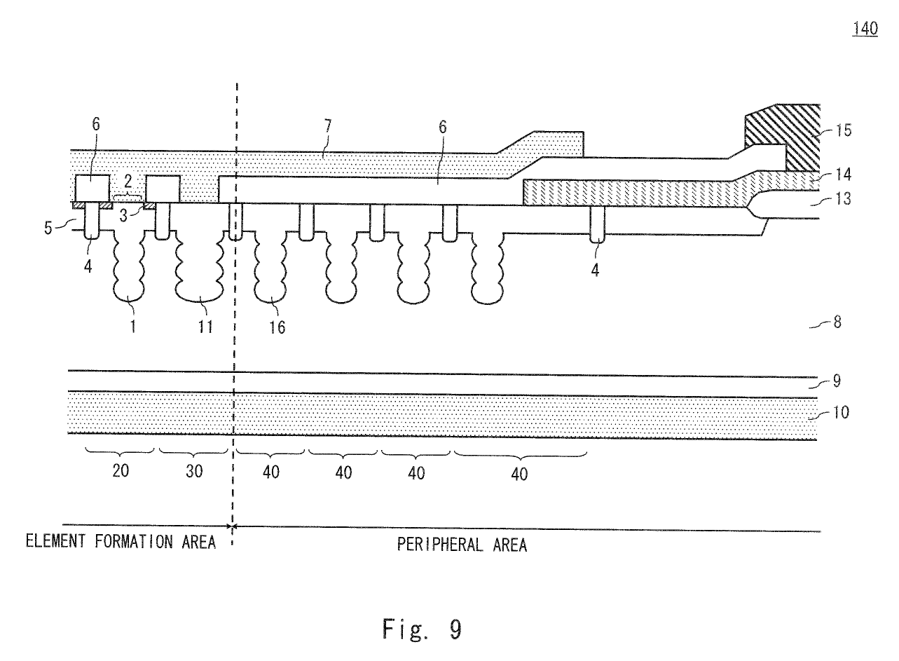

The structure of a semiconductor device according to another exemplary embodiment of the present invention is described hereinafter with reference to FIGS. 8 and 9. FIG. 8 is a plan layout view of a semiconductor device 140 according to a fifth exemplary embodiment. FIG. 9 is a cross-sectional view along line IX-IX in FIG. 8. For convenience of description, the illustration of some of the elements is omitted in FIG. 8.

The semiconductor device 140 according to the exemplary embodiment includes an element formation area and a peripheral area as shown in FIGS. 8 and 9. In the element formation area, unit cells are periodically arranged as shown in the dotted line in FIG. 8, as in the first exemplary embodiment. FIG. 8 shows the case where square unit cells are arranged alternately (square staggered arrangement) by way of illustration. The pitch size of the unit cell is 5 μm, for example. In the element formation area, an SJ-MOSFET cell in which an SJ-MOSFET 20 is formed and a diode cell in which a diode 30 is formed are disposed. The SJ-MOSFET cell or the diode cell is formed in each unit cell placed in the element formation area. Accordingly, the area through which the on-current flows is the element formation area.

As described above, in this exemplary embodiment, a part of a plurality of SJ-MOSFET cells arranged regularly in the element formation area of the semiconductor device 140 is substituted with a diode cell. Therefore, in this exemplary embodiment, the plan shape of one SJ-MOSFET cell and the plan shape of one diode cell are the same, as in the first exemplary embodiment. Accordingly, the diode cell has the same area as the SJ-MOSFET cell. In this exemplary embodiment, the arrangement of the diode cells is different from that of the first exemplary embodiment. The other structure in the element formation area is the same as that of the first exemplary embodiment and thus not repeatedly described. The arrangement of the diode cells is described later.

On the other hand, the peripheral area is an area located adjacent to the outside of the element formation area, as shown in FIGS. 8 and 9. Although only a part of the peripheral area is illustrated in FIG. 8, the peripheral area is placed surrounding the element formation area, for example. In the peripheral area, an element separation region 13, a field electrode 14, an electrode 15 and a dummy cell 40 are placed.

The element separation region 13 is formed from the top of the end of the base region 5 to the top of the epitaxial layer 8 located outside as shown in FIG. 9. The peripheral area ends at the element separation region 13. Further, the dummy cell 40 is formed in the part inner than the element separation region 13. In this example, a plurality of dummy cells 40 are placed in the peripheral area. In the dummy cell 40, a column region 16 of the second conductivity type is placed in the epitaxial layer 8 between the adjacent gate electrodes 4. In the epitaxial layer 8, the column region 16 is formed in an island shape in each dummy cell 40. The column region 16 is substantially the same as the column region 1 of the SJ-MOSFET cell, thus having substantially the same shape, size (width) and depth, for example.

In the peripheral area, the field electrode 14 is formed on the outside of the part where the column regions 16 are disposed. The field electrode 14 is formed continuously from the top of the base region 5 to the top of the element separation region 13. The field electrode 14 formed in this manner is connected -to the gate electrode 4 in the part on the outside of the column regions 16. The gate electrode 4 in the element formation area is thereby electrically connected to the field electrode 14. The field electrode 14 is further connected to the electrode 15 formed on top of it.

In the dummy cell 40, the source region 3 is not formed on the surface layer of the base region 5. Further, in the dummy cell 40, the interlayer insulating film 6 is formed to cover the gate electrode 4 and the base region 5. Thus, the interlayer insulating film 6 covers all over the dummy cell 40. Accordingly, the base region 5 of the dummy cell 40 is not connected to the source electrode 7. In this way, the dummy cell 40 is a cell that is not in contact with the source electrode 7. Further, the interlayer insulating film 6 is formed on the field electrode 14, extending over the end of the field electrode 14 on the element formation area side.

The arrangement of the diode cells is described hereinafter in detail. In this exemplary embodiment, the diode cells are placed adjacent to the peripheral area. Thus, the diode cells are disposed in the unit cells of the element formation area which are located adjacent to the peripheral area. The diode cells placed in the position adjacent to the peripheral area are arranged along the boundary between the element formation area and the peripheral area. Thus, if the peripheral area is formed to surround the element formation area, for example, the unit cells located on the outermost periphery of the element formation area are the diode cells. In this manner, among the SJ-MOSFET cells arranged regularly in the element formation area, the SJ-MOSFET cells adjacent to the peripheral area are substituted with the diode cells. By arranging the diode cells along the peripheral area on the boundary with the peripheral area, the following advantages can be obtained.

The breakdown voltage of a power device is determined by the lower one of the breakdown voltage of the element formation area and the breakdown voltage of the peripheral area. Therefore, it is generally designed -to suppress the current density in the event of breakdown in order that the breakdown voltage of the peripheral area having a smaller occupation area is higher than the breakdown voltage of the element formation area having a larger occupation area (the breakdown voltage of the element formation area<the breakdown voltage of the peripheral area).

However, in some cases, the breakdown voltage of the peripheral area becomes equal to or higher than the breakdown voltage of the element formation area (the breakdown voltage of the element formation area≦the breakdown voltage of the peripheral area) due to manufacturing variations or the like. In such a case, the breakdown current is concentrated in the vicinity of the boundary between the element formation area and the peripheral area. Therefore, in this case, it is possible to share the breakdown current by the entire diode cells placed along the peripheral area on the boundary with the peripheral area in the semiconductor device 140 according to the exemplary embodiment It is thereby possible to obtain sufficient avalanche capability.

When using the diode cells, it is necessary that the number of diode cells is limited to within a certain ratio with respect to the number of SJ-MOSFET cells. This is because the on-current does not flow through the diode cell where the source region 3 is not formed and therefore all of the R_{ct} component, the R_{ch} component and the Rₑₚᵢ component, which are the on-resistance component, increase.

For example, 1i the case of a chip of the maximum on-board class of a certain package, if the SJ-MOSFET cells adjacent to the peripheral area are substituted with the diode cells, the number of SJ-MOSFET cells is about 460,000, and the number of diode cells placed along the boundary with the peripheral area is about 3,000. In this case, the ratio of the number of diode cells with respect to the number of SJ-MOSFET cells is 0.65%. This ratio is lower than the ratio 4.0% of the case where one diode cell is placed per twenty-five SJ-MOSFET cells, which is described earlier as the example in which the on-resistance is reduced in the first exemplary embodiment. Thus, in the case of the chip of the maximum on-board class of the package described above, if the SJ-MOSFET cells adjacent to the peripheral area are substituted with the diode cells, the on-resistance is reduced overall compared to the case where the SJ-MOSFET cells are not substituted with the diode cells.

As described in the foregoing, in this exemplary embodiment, when substituting a part of the SJ-MOSFET cells with the diode cell, the diode cells are arranged particularly along the peripheral area on the boundary with the peripheral area. By sharing the breakdown current by the diode cells arranged in this manner as a whole, it is possible to improve the avalanche capability in the case of “the breakdown voltage of the element formation area≦the breakdown voltage of the peripheral area”. Further, the same advantages as the first exemplary embodiment can be obtained, and it is possible to further reduce the on-resistance while maintaining the breakdown voltage. It is thereby possible to provide the semiconductor device having a high breakdown voltage and low on-resistance with a simple structure.

Although the case where the column regions 1, 11 and 16 are formed continuously in the depth direction with a depth that does not reach the interface of the epitaxial layer 8 with the semiconductor substrate 9 is described in this exemplary embodiment, the depth of the column regions and the shape of the column regions are not limited thereto.

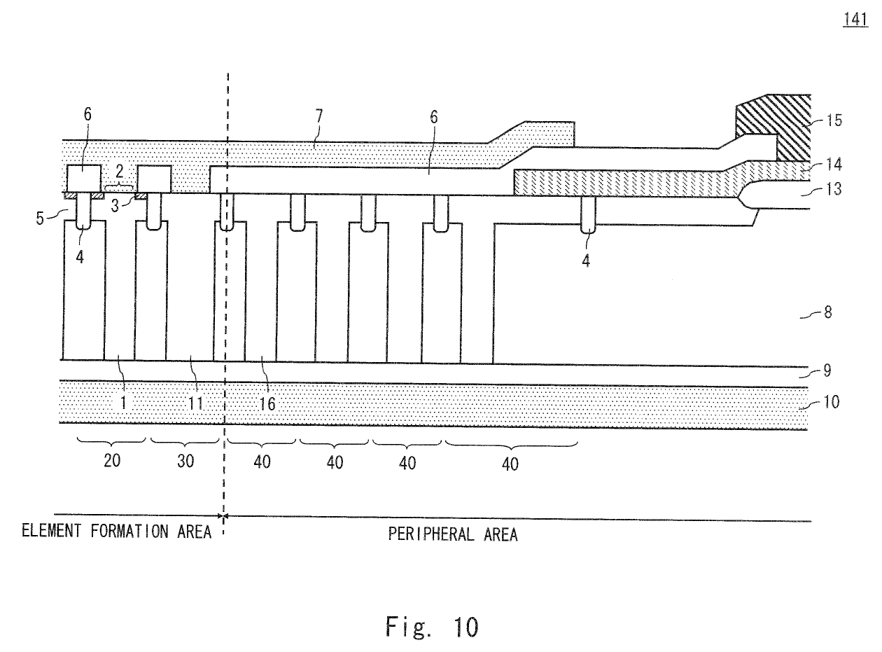

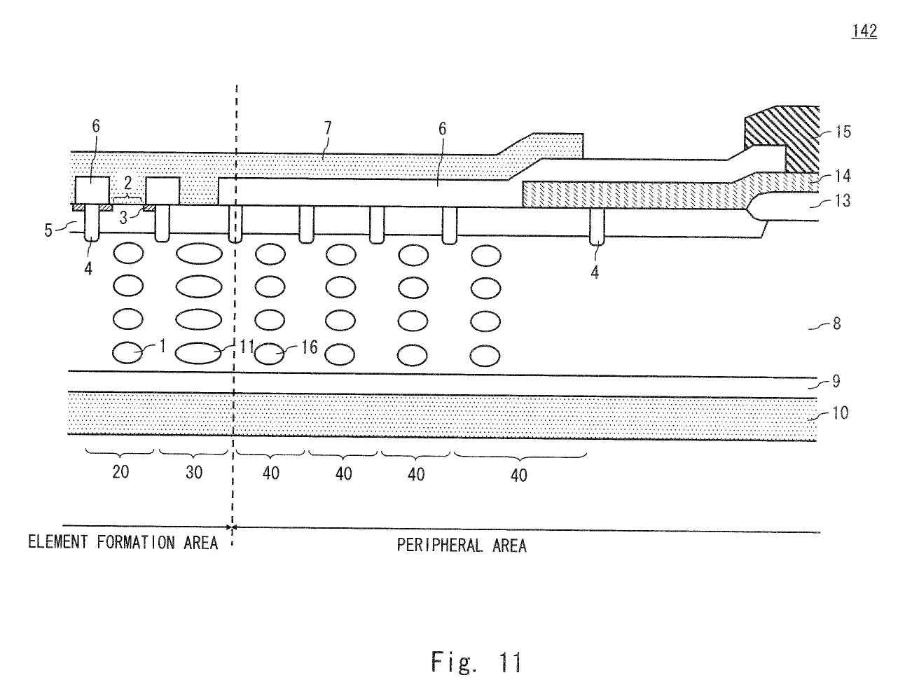

FIG. 10 is a cross-sectional view of a semiconductor device 141 according to another example of the fifth exemplary embodiment FIG. 10 is a cross-sectional view along line IX-IX in FIG. 8, just like FIG. 9. For example, the column regions 1, 11 and 16 may be formed continuously in the depth direction (the vertical direction in FIG. 10) with a depth that reaches the interface of the epitaxial layer 8 with the semiconductor substrate 9 as shown in FIG. 10. In this manner, the fifth exemplary embodiment may be used in combination with the third exemplary embodiment.

FIG. 11 is a cross-sectional view of a semiconductor device 142 according to yet another example of the fifth exemplary embodiment. FIG. 11 is a cross-sectional view along line IX-IX in FIG. 8, just like FIGS. 9 and 10. For example, the column regions 1, 11 and 16 may be formed discontinuously in the thickness direction of the epitaxial layer 8 (the vertical direction in FIG. 11). In this manner, the fifth exemplary embodiment may be used in combination with the fourth exemplary embodiment.

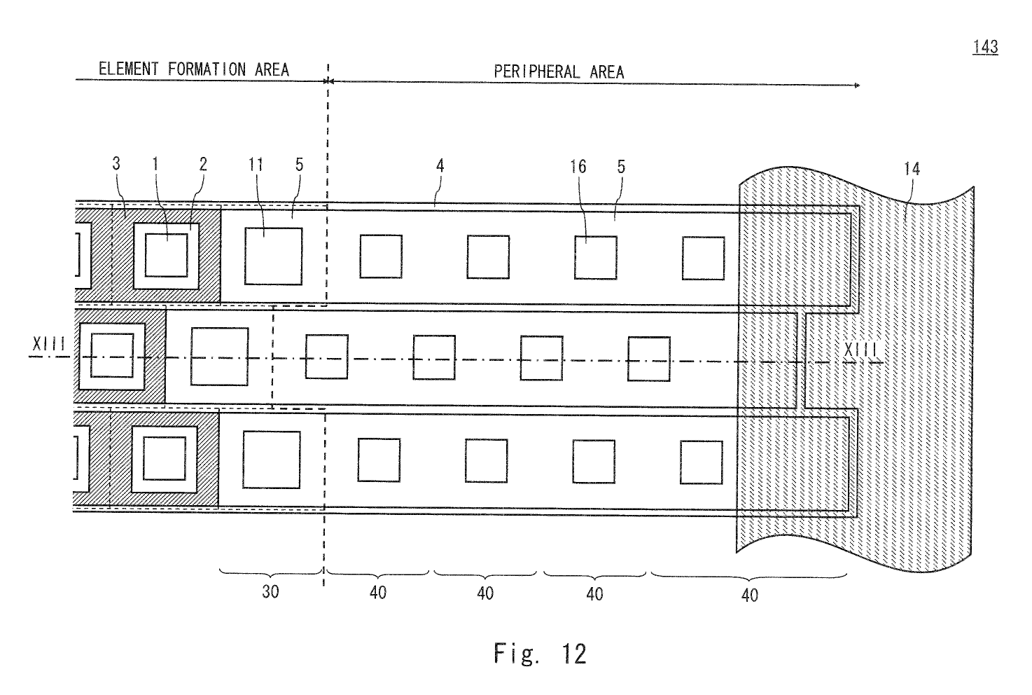

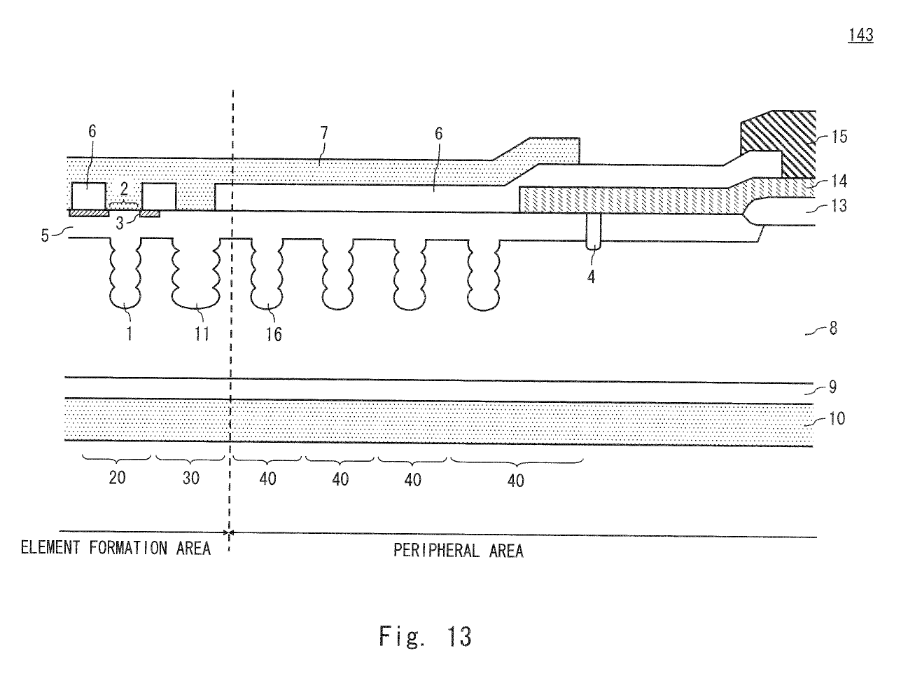

Further, although the case where the gate electrodes 4 are formed in a mesh pattern on the principal surface of the semiconductor substrate 9 is described in this exemplary embodiments the layout of the gate electrodes 4 is also not limited thereto. FIG. 12 is a plan layout view of a semiconductor device 143 according to still another example of the fifth exemplary embodiment. FIG. 13 is a cross-sectional view along line XIII-XIII in FIG. 12. For example, a plurality of gate electrodes 4 that are formed linearly in one direction on the principal surface of the semiconductor substrate 9 may be arranged in parallel with each other as shown in FIGS. 12 and 13. In this manner, the fifth exemplary embodiment may be used in combination with the second exemplary embodiment.

### Sixth Exemplary Embodiment

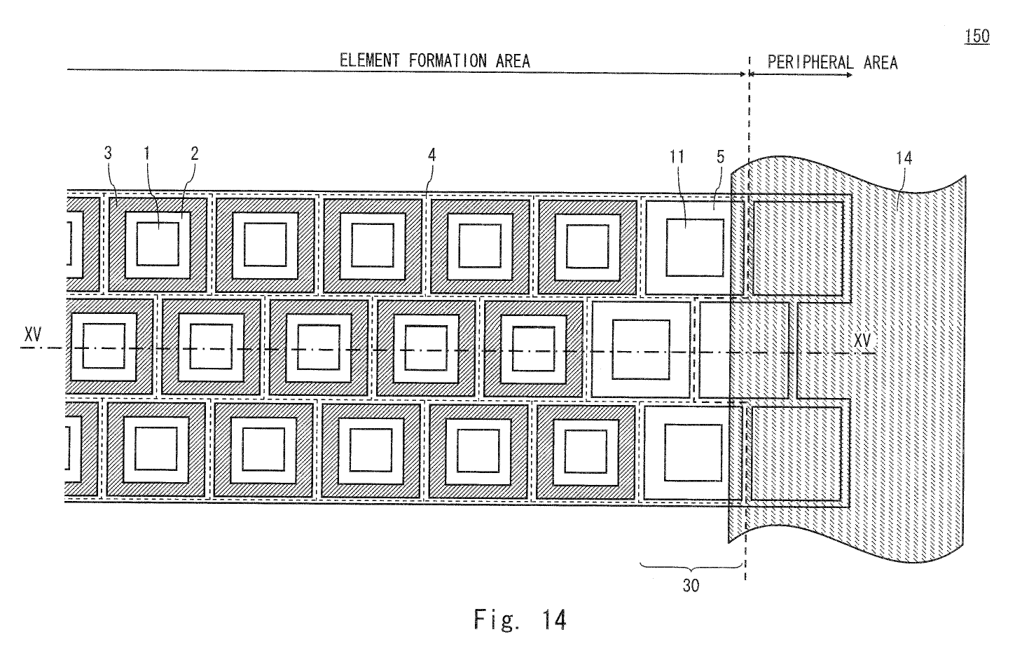

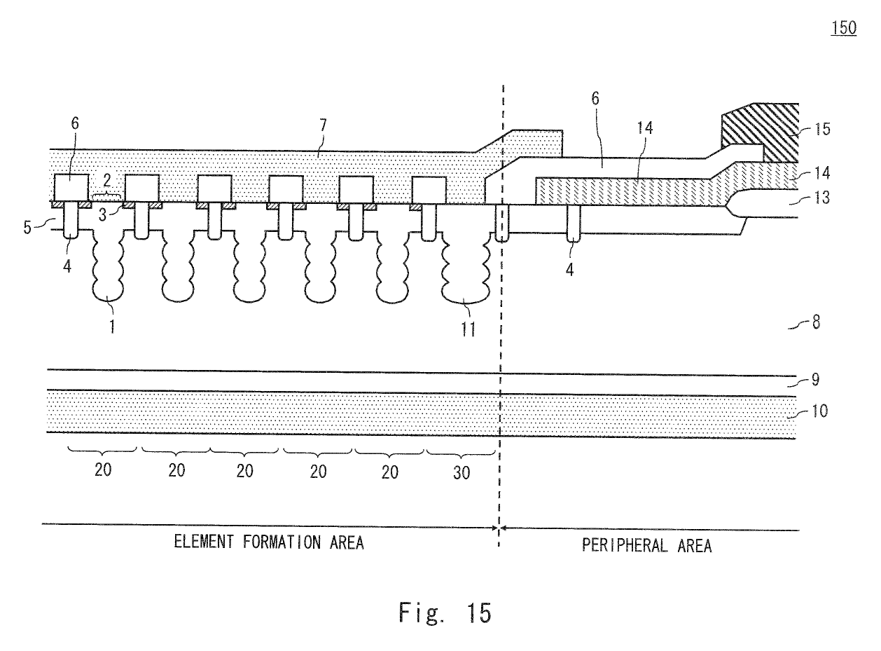

The structure of a semiconductor device according to another exemplary embodiment of the present invention is described hereinafter with reference to FIGS. 14 and 15. FIG. 14 is a plan layout view of a semiconductor device 150 according to a sixth exemplary embodiment. FIG. 15 is a cross-sectional view along line XV-XV in FIG. 14. For convenience of description, the illustration of some of the elements is omitted in FIG. 14. In this exemplary embodiment, the structure of the peripheral area is different from that of the fifth exemplary embodiment. The other structure is the same as that of the fifth exemplary embodiment and thus not repeatedly described.

Referring to FIGS. 14 and 15, in the semiconductor device 150 according to the exemplary embodiment, the dummy cell 40 is not formed in the peripheral area. Accordingly, in the peripheral area, the element separation region 13, the field electrode 14 and the electrode 15 are placed. Therefore, the field electrode 14 is formed on the outside of the part where the column region 11 is placed in the diode cell adjacent to the peripheral area. The field electrode 14 is formed continuously from the top of the base region 5 to the top of the element separation region 13. The field electrode 14 formed in this manner is connected to the gate electrode 4 in the part on the outside of the column region 11. The gate electrode 4 in the element formation area is thereby electrically connected to the field electrode 14, as in the fifth exemplary embodiment. The interlayer insulating film 6 formed on the field electrode 14 covers the end of the field electrode 14 on the element formation area side.

In this exemplary embodiment, the arrangement of the diode cells is the same as that of the fifth exemplary embodiment, and the diode cells are arranged along the peripheral area on the boundary with the peripheral area.

As described above, in this exemplary embodiment, the peripheral area does not have the part where the dummy cell that is not in contact with the source electrode 7 is formed. The occupation area of the peripheral area in the semiconductor device 150 is thereby reduced. Accordingly, the occupation area of the element formation area in the semiconductor device 150 is enlarged. It is thereby possible to enlarge the area of the element formation area with the same chip size, thus enabling further reduction of the on--resistance. Further, the same advantages as the fifth exemplary embodiment can be obtained.

### Seventh Exemplary Embodiment

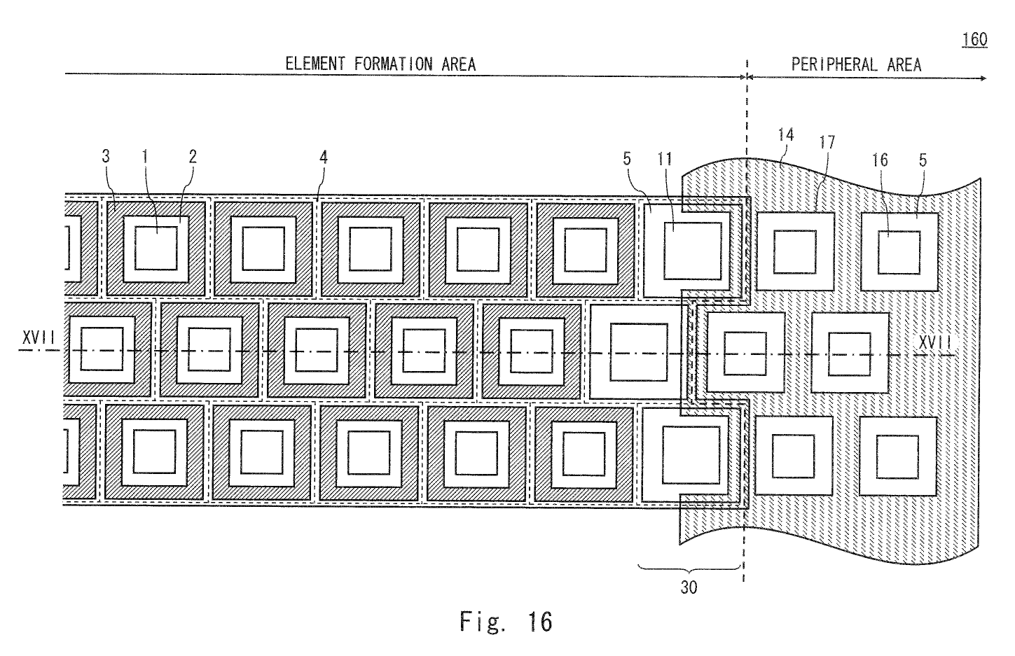

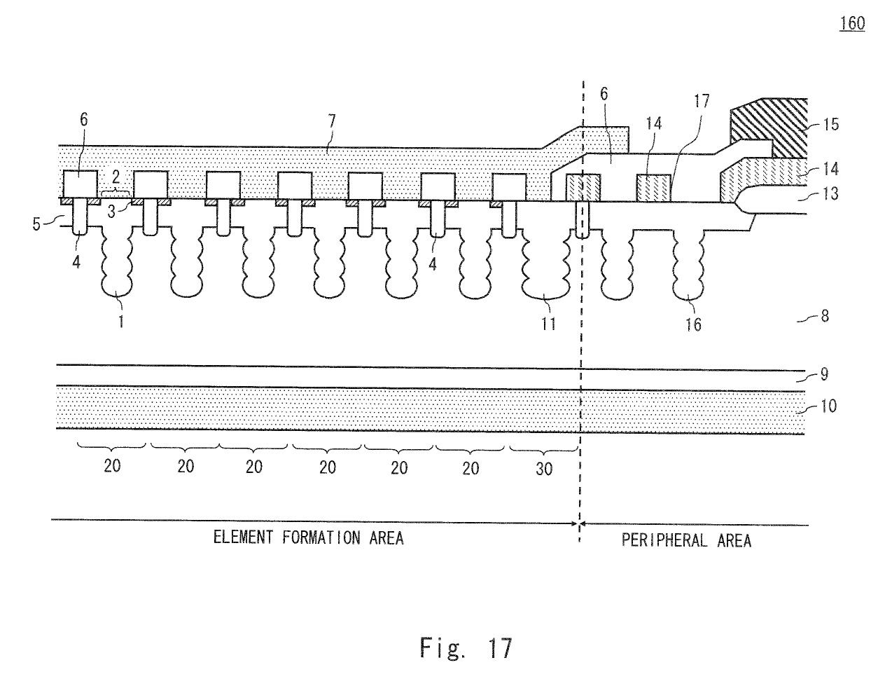

The structure of a semiconductor device according to another exemplary embodiment of the present invention is described hereinafter with reference to FIGS. 16 and 17. FIG. 16 is a plan layout view of a semiconductor device 160 according to a seventh exemplary embodiment. FIG. 17 is a cross-sectional view along line XVII-XVII in FIG. 16. For convenience of description, the illustration of some of the elements is omitted in FIG. 16. In this exemplary embodiment, the structure of the peripheral area is different from that of the fifth exemplary embodiment. The other structure is the same as that of the fifth exemplary embodiment and thus not repeatedly described.

Referring to FIGS. 16 and 17, in the semiconductor device 160 according to the exemplary embodiment, the dummy cell 40 is not formed in the peripheral area. Further, the field electrode 14 is formed on the outside of the part where the column region 11 is formed in the diode cell adjacent to the peripheral area. The field electrode 14 is formed continuously from the top of the base region 5 to the top of the element separation region 13. The field electrode 14 formed in this manner is connected to the gate electrode 4 in the part on the outside of the column region 11. The gate electrode 4 in the element formation area is thereby electrically connected to the field electrode 14, a in the fifth exemplary embodiment.

In this exemplary embodiment, the field electrode 14 has an opening 17. Further, the column region 16 of the second conductivity type is formed inside the opening 17 when viewed from above. In the epitaxial layer 8, the column region 16 is formed in an island shape in each opening 17. The column region 16 is substantially the same as the column region 1 of the SJ-MOSFET cell, thus having substantially the same shape, size (width) and depth, for example. The interlayer insulating film 6 formed on the field electrode 14 covers the end of the field electrode 14 on the element formation area side and the opening 17.

In this exemplary embodiment, the arrangement of the diode cells is the same as that of the fifth exemplary embodiment, and the diode cells are arranged along the peripheral area on the boundary with the peripheral area.

As described above, in this exemplary embodiment, the field electrode 14 has the opening 17, and the column region 16 is formed in the peripheral area. It is thereby possible to increase the breakdown voltage in the peripheral area. Further, the same advantages as the fifth exemplary embodiment can be obtained.

### Eighth Exemplary Embodiment

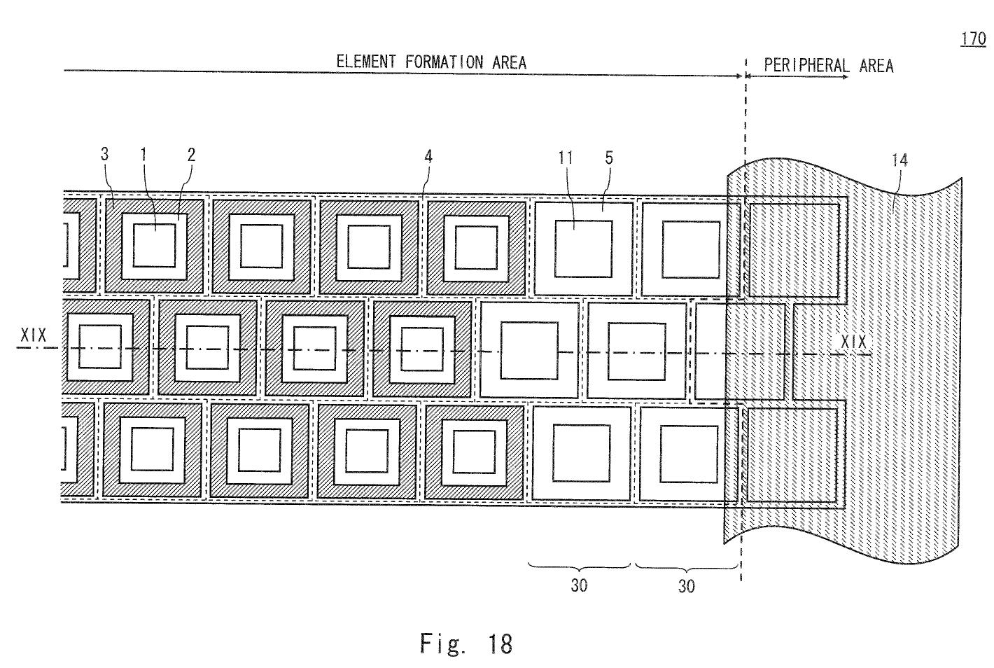

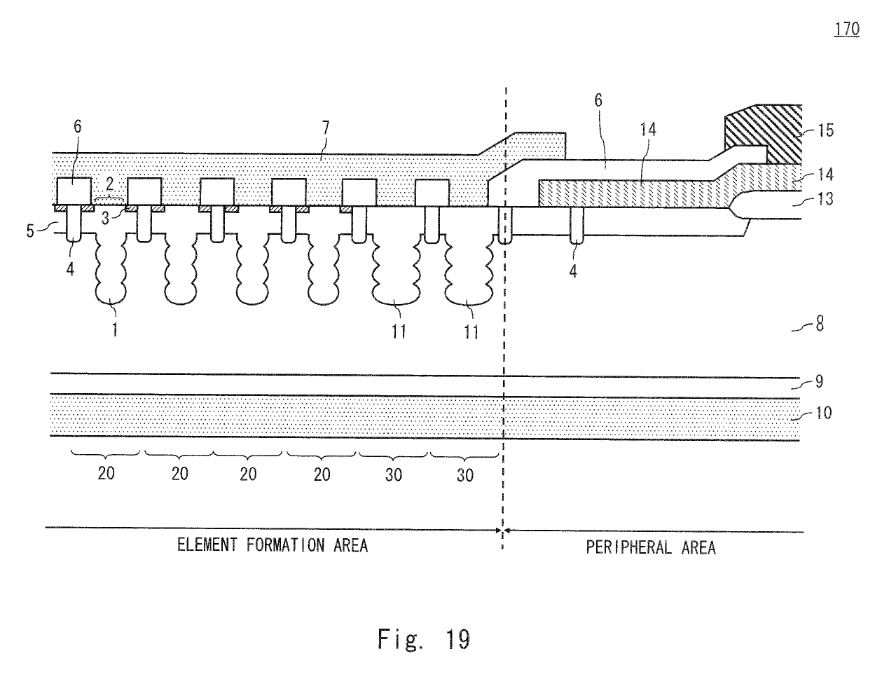

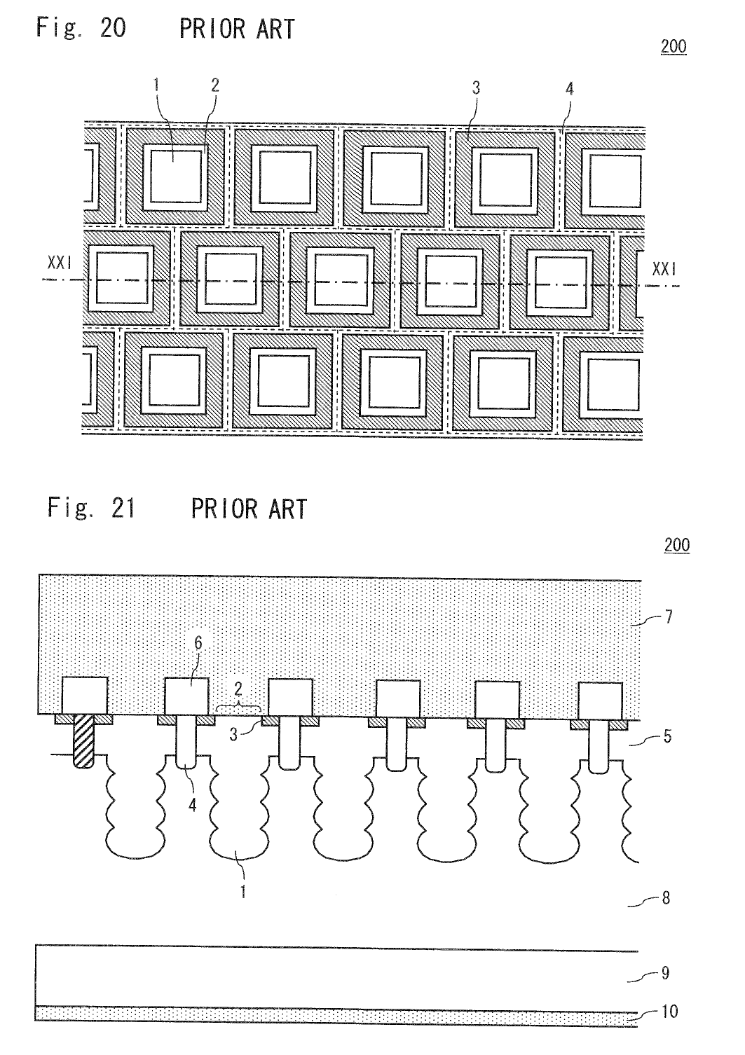

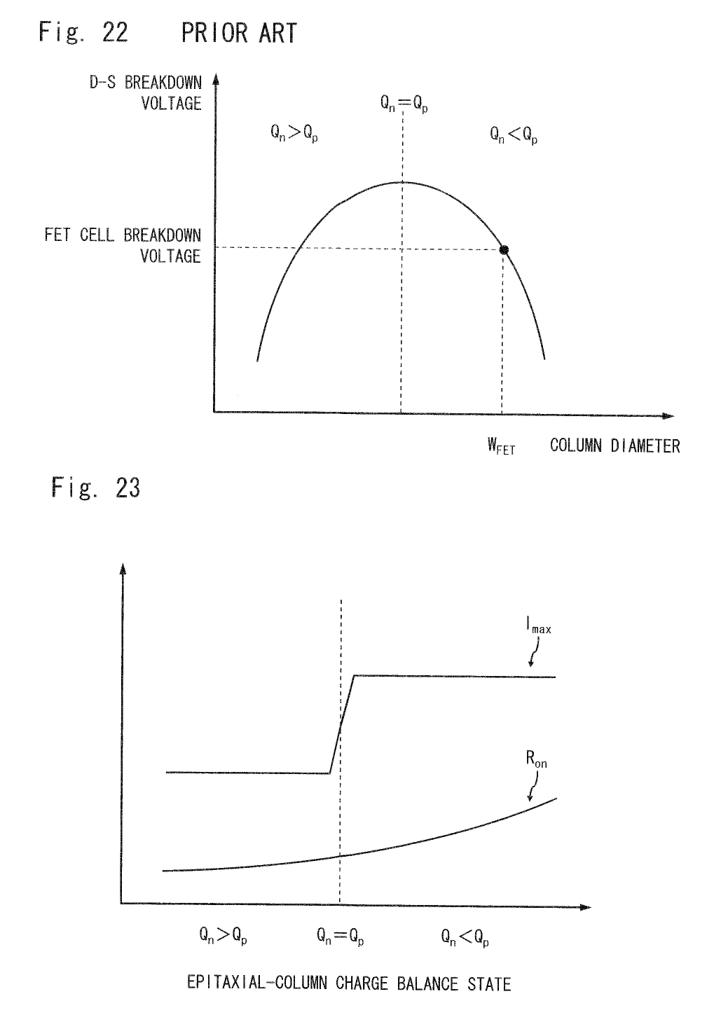

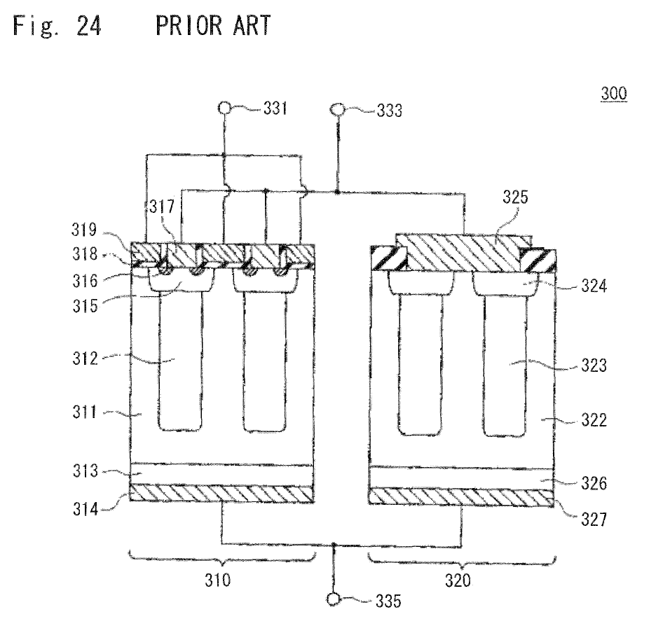

The structure of a semiconductor device according to another exemplary embodiment of the present invention is described hereinafter with reference to FIGS. 18 and 19. FIG. 18 is a plan layout view of a semiconductor device 170 according to an eighth exemplary embodiment. FIG. 19 is a cross-sectional view along line XIX-XIX in FIG. 18. For convenience of description, the illustration of some of the elements is omitted in FIG. 18. In this exemplary embodiment, the arrangement of the diode cells is different from that of the sixth exemplary embodiment. The other structure is the same as that of the sixth exemplary embodiment and thus not repeatedly described.

Referring to FIGS. 18 and 19, in the semiconductor device 170 according to the exemplary embodiment, a plurality of rows of the diode cells are formed along the peripheral area on the boundary with the peripheral area. Thus, the diode cell is placed not only in the unit cell located adjacent to the peripheral area but also in the unit cell located on the inner side. Therefore, among the SJ-MOSFET cells arranged regularly in the element formation area, a plurality of rows of the SJ-MOSFET cells on the boundary with the peripheral area are substituted with the diode cells. This increases the number of the diode cells capable of sharing the breakdown current.

In this example, two rows of the diode cells are disposed on the boundary with the peripheral area. Accordingly, the diode cell is placed in the unit cell of the element formation area located adjacent to the peripheral area and also in the different unit cell located adjacent to the above unit cell on the element formation area side. This substantially doubles the number of the diode cells capable of sharing the breakdown current.

As described in the foregoing, in this exemplary embodiment, when substituting a part of the SJ-MOSFET cells with the diode cell, the diode cells are arranged in a plurality of rows along the peripheral area on the boundary with the peripheral area. By increasing the number of the diode cells capable of sharing the breakdown current, the current density is suppressed, thus avoiding the thermal breakdown. It is thereby possible to further improve the avalanche capability. Further, the same advantages as the sixth exemplary embodiment can be obtained.

Although the case where the unit cells are placed in square staggered arrangement is described by way of illustration in the first to eighth exemplary embodiments, the shape and the arrangement of the unit cells are not limited thereto and may be varied as appropriate. For example, the shape of the unit cell may be polygon, such as hexagon. Further, the stripe-like gate electrodes 4 may be arranged in parallel in the respective directions, so that they are in lattice pattern. Further, the first to eighth exemplary embodiments can be combined as desirable by one of ordinary skill in the art.

For example, although the case where the gate electrodes 4 are formed in a mesh pattern is described by way of illustration in the sixth to eighth exemplary embodiments, the gate electrodes 4 may be a stripe pattern as described in the second and fifth exemplary embodiments. Further, in the sixth to eighth exemplary embodiments also, the depth of the column region and the shape of the column region may be varied as described in the third to fifth exemplary embodiments. Furthermore, although combination with the structure of the peripheral area described in the sixth exemplary embodiment is described in the eighth exemplary embodiment above, the eighth exemplary embodiment may be combined with the structure of the peripheral area described in the fifth or seventh exemplary embodiment.

Further, although the arrangement of the diode cells in the part other than the boundary of the element formation area with the peripheral area is not mentioned in the fifth to eighth exemplary embodiments, the arrangement of the diode cells in this part may be determined arbitrarily. Therefore, the diode cells may be placed only on the boundary of the element formation area with the peripheral area. Alternatively, the diode cells may be placed in the other part of the element formation area in addition to the boundary of the element formation area with the peripheral area. In this case, the diode cells may be arranged periodically or randomly in the part of the element formation area other than the boundary with the peripheral area, as in the first exemplary embodiment. Thus, the diode cells may be interspersed in the part of the element formation area other than the boundary with the peripheral area.

While the invention has been described in terms of several exemplary embodiments, those skilled in the art will recognize that the invent ion can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A semiconductor device comprising:
a metal-oxide semiconductor field-effect transistor (MOSFET) cell having a super junction structure; and
a diode cell connected in parallel with the MOSFET cell and having the same plan shape as the MOSFET cell, wherein
the MOSFET cell includes:
an epitaxial layer of a first conductivity type formed on a semiconductor substrate,
a gate electrode formed in a trench of the epitaxial layer with an insulating layer interposed therebetween,
a first column region of a second conductivity type formed in the epitaxial layer,
a first base region of the second conductivity type formed on a surface of the epitaxial layer, and
a source region of the first conductivity type formed on a surface of the first base region, and
the diode cell includes:
a second column region of the second conductivity type formed in the epitaxial layer, the second column region having a larger width than the first column region, and
a second base region of the second conductivity type formed on the surface of the epitaxial layer.

2. The semiconductor device according to claim 1, wherein the gate electrode is further formed in the diode cell with the same layout as in the MOSFET cell.

3. The semiconductor device according to claim 2, wherein the gate electrode is placed respectively on periphery of the first column region and the second column region in a plan view.

4. The semiconductor device according to claim 1, wherein the source region is formed only in the MOSFET cell.

5. The semiconductor device according to claim 1, wherein a breakdown voltage of the diode cell is smaller than a breakdown voltage of the MOSFET cell.

6. The semiconductor device according to claim 1, wherein the super junction structure is formed by the epitaxial layer and the first column region.

7. The semiconductor device according to claim 1, further comprising:
an element formation area where the MOSFET cell is placed; and
a peripheral area located outside of the element formation area and having an element separation region,
wherein the diode cell is placed in substitution for a part of the MOSFET cell arranged regularly in the element formation area.

8. The semiconductor device according -to claim 7, wherein the diode cell is arranged periodically or randomly in the element formation area.

9. The semiconductor device according to claim 7, wherein the diode cell is placed on a boundary of the element formation area with the peripheral area.

10. The semiconductor device according to claim 9, wherein the diode cell is arranged along the peripheral area.

11. The semiconductor device according to claim 10, wherein the diode cell is placed in a plurality of rows.
